(19) United States
(12) Patent Application Publication
(10) Pub. No.: US 2023/0231076 A1
(43) Pub. Date: Jul. 20, 2023

(54) OPTOELECTRONIC DEVICE AND MANUFACTURING METHOD THEREOF

(71) Applicant: ALEDIA, Echirolles (FR)

(72) Inventors: Jérôme NAPIERALA, Saint Egreve (FR); Florian DUPONT, Grenoble (FR)

(21) Appl. No.: 17/928,755

(22) PCT Filed: May 26, 2021
(86) PCT No.: PCT/EP2021/064104

§ 371 Date: Nov. 30, 2022

(30) Foreign Application Priority Data
Jun. 1, 2020 (FR) FR2005750

(51) Int. Cl. H01L 33/32; H01L 33/24; H01L 33/62; H01L 33/00

(52) U.S. Cl. CPC H01L 33/32; H01L 33/24; H01L 33/62; H01L 33/0075; H01L 2933/0066

(57) ABSTRACT

A three-dimensional (3D) structure for optoelectronics including a pyramid made of a first InGaN-based material formed from a substrate, wherein the 3D structure includes a wire made of a second GaN-based material, different from the first material, the wire extending in a longitudinal direction perpendicular to the plane of the substrate between the substrate and a base of the InGaN-based pyramid, so that the 3D structure has the general shape of a pencil. One or more embodiments of the invention also relates to a method for manufacturing such a 3D structure, and an optoelectronic device based on a plurality of these 3D structures.

### TECHNICAL FIELD

The invention relates to the field of optoelectronics. It finds a particularly advantageous application in the field of light-emitting diodes based on gallium nitride (GaN) having a three-dimensional structure.

### PRIOR ART

Light-emitting diodes (LED) typically comprise a region called active region where radiative recombinations of electron-hole pairs occur, which allow to obtain light radiation having a main wavelength.

For display applications, LEDs can be configured to produce light radiation with a primary wavelength in the blue, or in the green, or in the red.

This main wavelength depends in particular on the composition of the active region. To produce light radiation in the green or in the red, the active region can typically be based on InGaN. The more the concentration of indium [In] increases, the more the main wavelength increases. It may therefore be necessary to incorporate a concentration of indium [In]≥10 at % to obtain a LED emitting in the red.

GaN-based LEDs are generally manufactured according to a technology called planar technology, which consists in forming on a base plane of a substrate, a stack of two-dimensional (2D) layers in a direction normal to the base plane.

This stack may typically comprise, from the substrate, a GaN buffer region, an N doped GaN region, the active InGaN-based region, a P doped GaN region.

Structuring this stack a posteriori, for example by lithography/etching steps, then allows to form a plurality of LEDs or micro-LEDs each having a mesa structure typically comprising a top face and side walls (FIG. 1).

For high indium concentrations however, for example [In]≥10 at %, the mismatch of lattice parameters between the GaN-based regions and the InGaN-based active region 22 causes mechanical stresses which ultimately generate, by plastic relaxation, the creation of structural defects. These structural defects affect the radiative efficiency of LEDs or micro-LEDs. In particular, it is particularly difficult to obtain red LEDs with good radiative efficiency.

Another drawback of this type of mesa structure is related to the posterior structuring. The side walls 200 obtained by etching generally have defects promoting the appearance of non-radiative surface recombinations. The radiative efficiency of LEDs is further reduced.

One solution for reducing side wall defects is to directly form a GaN-based three-dimensional (3D) structure. These 3D structures can be in the shape of pyramids as illustrated in FIG. 2. To further limit the phenomenon of plastic stress relaxation, these pyramids can comprise a bulk InGaN region underlying the active region 22. The document “Nanoscale selective area growth of thick, dense, uniform, In-rich, InGaN nanostructure arrays on GaN/sapphire template, S. Sundaram and al., Journal of Applied Physics 116, 163105 (2014)” discloses for example bulk InGaN pyramidal regions. Such a bulk InGaN pyramidal region 21 is referred to as an “InGaN pyramid” hereinafter.

The growth of the InGaN pyramids can be done by epitaxy from a GaN layer 11 partially covered by a masking layer 12.

A disadvantage of the InGaN pyramids 21 thus formed is that they can have a large number of structural defects. The crystalline quality of the bulk InGaN region is therefore not sufficient to manufacture optoelectronic devices, in particular LEDs, with satisfactory performance.

To improve the crystalline quality of the epitaxial InGaN pyramids 21, one solution consists in growing these pyramids 21 from a GaN buffer layer 11. Such a buffer layer 11 is in particular thicker than a conventional thin layer. The buffer layer 11 allows to confine the structural defects in a lower part of the layer 11—at an interface with the underlying support 10, for example made of silicon. As the concentration of these structural defects generally decreases along the thickness of the layer, the GaN buffer layer 11 has improved crystal quality in its upper part. The use of such thick GaN buffer layers 11 however generates curvature problems for a silicon support 10 in the shape of a wafer. Such buffer layers are furthermore expensive to produce.

Another disadvantage of this type of pyramidal structure is that the incorporation of indium in the bulk InGaN region 21 remains limited, even on a GaN buffer layer 11. In particular, it is difficult to form InGaN pyramids 21 having an indium concentration [In]≥10 at % with satisfactory crystalline quality. Therefore, these 3D pyramidal InGaN-based structures do not allow to form micro-LEDs emitting in the red with a satisfactory radiative efficiency.

The present invention aims at least at partially overcoming some of the drawbacks mentioned above.

In particular, an object of the present invention is to provide a three-dimensional structure comprising InGaN pyramids with improved crystal quality.

Another object of the present invention is to provide a method for forming InGaN pyramids allowing to reduce the manufacturing costs and/or to improve the crystal quality of InGaN pyramids.

Another object of the present invention is to provide an optoelectronic device, in particular a GaN-based 3D LED, comprising InGaN pyramids emitting in the red or in the green with improved radiative efficiency.

The other objects, features and advantages of the present invention will become apparent upon examining the following description and the accompanying drawings. It is understood that other advantages can be incorporated.

### SUMMARY

To achieve the objects mentioned above, the present invention provides according to a first aspect a three-dimensional (3D) structure for optoelectronics comprising a pyramid made of a first InGaN-based material formed from a planar substrate.

Advantageously, the 3D structure comprises a wire made of a second GaN-based material, different from the first material, said wire extending in a longitudinal direction perpendicular to the plane of the substrate between said substrate and a base of the InGaN-based pyramid, so that the 3D structure has the general shape of a pencil.

The GaN-based wire thus acts as a 3D substrate for the InGaN-based pyramid. This 3D substrate in the shape of a wire advantageously replaces a planar substrate in the shape of a thick GaN buffer layer. This substrate in the shape of wire is in particular of better crystalline quality and more economical to produce than a thick GaN planar substrate.

Such a GaN-based wire is preferably obtained by growing from the bottom to top, according to an approach called “bottom-up” approach, rather than by etching from top to bottom, according to the reverse approach called “top-down”. Such “bottom-up” growth limits the appearance of mechanical stresses within the GaN, in particular thanks to the presence of free surfaces at the walls of the wire during growth. This allows to limit the occurrence of structural defects within the wire, thereby improving the crystalline quality of the GaN-based wire. This also allows to limit or eliminate the appearance of surface defects on the walls of the wire, unlike the “top-down” approach which promotes the appearance of these surface defects.

Furthermore, the wire-shaped growth has a better efficiency than the growth of bulk layers. The surface area to volume ratio of a wire is indeed greater than that of a planar layer. As growth is limited by surface phenomena, the growth efficiency is therefore higher in the case of wire-shaped growth. This allows to reduce the production cost of the GaN-based substrate of the prior art by transposing it in the shape of wires.

Such a substrate in the shape of wires can also advantageously be formed on a silicon wafer of large dimensions, for example 8 inches or 12 inches, without the latter suffering from problems of curvature. The mechanical stresses related to the difference in lattice parameter between silicon and a GaN-based material are largely relaxed by a growth of this material in the shape of wires, in comparison with a growth of this material in the shape of a layer—for equal layer thickness and wire height.

A second aspect of the present invention relates to an optoelectronic device based on gallium nitride (GaN) comprising a plurality of three-dimensional (3D) structures according to the first aspect of the invention.

The 3D structures are advantageously spaced from each other by a separation distance ds less than or equal to 650 nm, preferably less than or equal to 600 nm.

Developments leading to the present invention have allowed to identify that a high GaN-based wire density promoted the growth of InGaN-based structures at the top of the wires, rather than on the walls of the wires. According to a technical prejudice, growth by vapour phase epitaxy with organometallic precursors MOVPE produces substantially conformal layers on the surface of a substrate, whether it is structured or not. Thus, according to this prejudice, a MOVPE deposition of InGaN on a GaN-based wire forms a structure called radial 3D structure, having a continuous layer of InGaN on the walls and the top of the wire.

On the contrary, within the framework of the development of the present invention, it appeared that such a MOVPE deposition of InGaN on a set of GaN-based wires sufficiently close to each other, allows to obtain a structure called axial 3D structure, where the InGaN-based material is mainly located on the top of the wires.

Furthermore, unexpectedly, these InGaN-based top structures grow as pyramids rather than as wire-shaped layers. One probable explanation is that the proximity of the top structures disturbs the equilibrium of the thermodynamic system so as to lead to the formation of these pyramids.

According to one particular example, it has surprisingly appeared that the periodic deposition of InGaN wells and AlGaN barriers on a substrate in the shape of GaN-based wires spaced from each other by approximately 200 nm, ultimately leads to obtaining bulk InGaN-based pyramids at the top of the wires.

Under these conditions of high wire's density, for separation distances ds between wires less than or equal to 650 nm, indium is therefore distributed homogeneously during the formation of the top pyramidal structure.

Obtaining such bulk InGaN-based pyramids advantageously allows to grow active InGaN-based regions having an improved crystal quality and/or an increased indium concentration.

InGaN-based pyramids can advantageously have inclined faces corresponding to semi-polar planes. These semi-polar planes are for example of the {10-11} type. Such semi-polar planes promote the incorporation of indium compared to the non-polar planes of the walls of the wires. The top InGaN pyramids can thus have sufficient Indium concentrations, for example [In]≥10 at %, to form LEDs configured to emit light rays in the green or in the red, with improved radiative efficiency.

A third aspect of the present invention relates to a method for manufacturing a plurality of three-dimensional (3D) structures for optoelectronics each comprising an InGaN-based pyramid.

This method comprises the following steps:
Providing a substrate comprising at least one surface layer allowing nucleation and growth of GaN, for example based on GaN, AlN, and/or other metal nitride,
Depositing a masking layer on the GaN-based substrate, said masking layer comprising openings through which the surface layer is exposed,
Forming, by epitaxy from the exposed areas of the surface layer, GaN-based wires each extending from a base to a top in a longitudinal direction substantially perpendicular to the surface layer, said base being connected to the surface layer through the openings,
Forming, by epitaxy on the tops of GaN-based wires, InGaN-based pyramids.

The method thus allows to form InGaN-based pyramids from an advantageously thin surface layer, also called the nucleation layer. The epitaxial wires have a crystal quality higher than a bulk layer of equivalent thickness. These wires therefore advantageously form a 3D GaN-based substrate of good crystalline quality for the growth of InGaN-based pyramids. The crystal quality of the InGaN-based pyramids is thus improved.

GaN-based wire epitaxy is also more efficient and consumes fewer precursors than GaN-based bulk layer epitaxy. The method therefore ultimately allows to reduce the manufacturing costs of InGaN-based pyramids.

According to an advantageous possibility, the openings of the masking layer are regularly distributed in the shape of an array having a pitch less than or equal to 700 nm, for example between 50 nm and 650 nm. This pitch partly determines the separation distance ds between wires. After the growth of GaN-based wires, they are therefore relatively close to each other. This allows to promote axial growth of InGaN at the top of the wires, in the shape of pyramids.

It is understood that the features and advantages of one aspect of the invention can be transposed, mutatis mutandis, to another aspect of the invention.

### BRIEF DESCRIPTION OF THE FIGURES

The purposes, objects, as well as the features and advantages of the invention will become more apparent from the detailed description of embodiments of the latter which are illustrated by the following accompanying drawings wherein:

FIG. 1 illustrates a 3D LED structure having a mesa structure according to the prior art.

FIG. 2 illustrates a 3D LED structure comprising InGaN-based pyramids according to the prior art.

FIG. 3 illustrates a 3D structure comprising an InGaN-based pyramid according to one embodiment of the present invention.

FIG. 4A is a scanning transmission electron microscopy (STEM) image of 3D structures according to one embodiment of the present invention.

FIG. 4B is an enlarged view of the image of FIG. 4A showing a top pyramid of a 3D structure according to one embodiment of the present invention.

FIG. 4C is an EDX mapping of FIG. 4B showing the distribution of Indium within a top pyramid of a 3D structure according to one embodiment of the present invention.

FIG. 5 is a scanning electron microscopy (SEM) image of an optoelectronic device comprising a plurality of 3D structures according to one embodiment of the present invention.

FIG. 6 is a scanning electron microscopy (SEM) image of an optoelectronic device comprising a plurality of 3D structures according to another embodiment of the present invention.

FIG. 7A is a cathodoluminescence image formed for a wavelength λ_{R} of the red light domain, in top view of the optoelectronic device illustrated in FIG. 6.

FIG. 7B is the image of FIG. 7A with an increased dynamic range of contrast, accentuating the differences in emission intensity at the wavelength λ_{R} of the top InGaN-based pyramids.

FIG. 7C is a hyperspectral image showing the cathodoluminescence emission spectra associated with each point of the spatial profile shown in FIG. 7B.

FIG. 8 is a photoluminescence spectrum of the optoelectronic device shown in FIG. 6.

FIG. 9 is a photoluminescence spectrum of an optoelectronic device comprising a plurality of 3D structures according to another embodiment of the present invention.

FIG. 10A is a scanning electron microscopy (SEM) image of an optoelectronic device comprising a plurality of 3D structures according to another embodiment of the present invention.

FIG. 10B is a photoluminescence spectrum of the optoelectronic device shown in FIG. 10A.

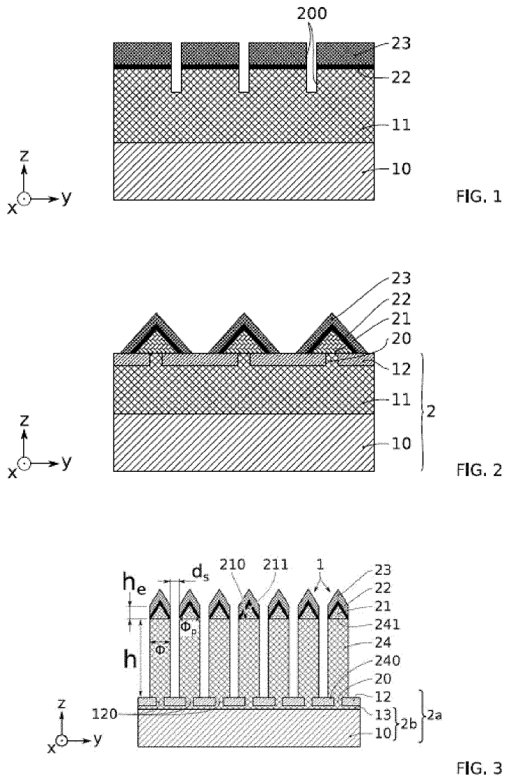

The drawings are given by way of example and are not limiting of the invention. They constitute schematic principle representations intended to facilitate the understanding of the invention and are not necessarily on the scale of practical applications. In particular, the dimensions of the various elements of 3D structures are not necessarily representative of reality.

### DETAILED DESCRIPTION

Before starting a detailed review of embodiments of the invention, it is recalled that the invention according to its first aspect comprises in particular the optional features below which can be used in combination or alternatively.

According to one example, the wire has a height greater than or equal to 150 nm.

According to one example, the wire has a diameter greater than or equal to 30 nm and/or less than or equal to 500 nm.

According to one example, the InGaN-based pyramid has a base diameter and the wire diameter is less than or equal to the base diameter.

According to one example, the base of the InGaN-based pyramid is substantially parallel to the plane of the substrate.

According to one example, the GaN-based wire comprises a base resting on the planar substrate, and a top supporting the base of the InGaN-based pyramid, said top being surrounded by an InGaN-based collar.

According to one example, the InGaN-based pyramid comprises faces inclined at an angle of approximately 300 relative to the longitudinal direction, these inclined faces corresponding substantially to semi-polar planes of the {10-11} type.

According to one example, the 3D structure further comprises an active InGaN-based region on at least one face of the InGaN-based pyramid, said active region being configured to emit or receive light radiation.

According to one example, the InGaN-based pyramid has an indium level [In]≥10%.

According to one example, the InGaN-based pyramid has a height greater than or equal to 50 nm and/or less than or equal to 500 nm.

In one example, the diameter of the wire is greater than that of the opening of the masking layer.

The invention according to its second aspect comprises in particular the optional features below which can be used in combination or alternatively: According to one example, at least part of the 3D structures of the optoelectronic device is configured to emit light radiation having a main wavelength, and said main wavelength varies depending on a diameter 4) of the wires of said 3D structures and the separation distance ds separating two adjacent 3D structures among said 3D structures.

According to one example, the plurality of 3D structures has identical separation distances ds and identical wire diameters 4, said 3D structures being configured to emit light radiation having a main wavelength A partly determined by the diameter 4) and the separation distance ds, in particular for green 3D structures on the same plate (with the same growth conditions, in particular of the active layer).

According to one example, the optoelectronic device comprises at least first, second and third pluralities of 3D structures respectively having first, second and third separation distances ds1, ds2, ds3 and first, second and third diameters Φ1, Φ2, Φ3 of wires such that ds1<ds2<ds3 and Φ1>Φ2>Φ3, said first, second and third pluralities of 3D structures emitting light radiation respectively having first, second and third wavelengths λ1, λ2, λ3 different from each other and preferably such that λ1>λ2>λ3.

According to one example, the optoelectronic device comprises first and second pluralities of 3D structures respectively having first and second separation distances ds1, ds2, and first and second diameters Φ1, Φ2 of wires, such that ds1<ds2 and 1>Φ2, said first and second pluralities of 3D structures emitting light radiation respectively having first and second wavelengths λ1, λ2 different from each other and preferably such that λ1>λ2.

According to one example, the optoelectronic device comprises at least a first plurality of 3D structures having a first separation distance ds1 and a first diameter Φ1 of wires, said 3D structures emitting light radiation having a first wavelength λ1 belonging to the spectrum of red light.

According to one example, the optoelectronic device comprises at least a second plurality of 3D structures having a second separation distance ds2 and a second diameter Φ2 of wires, said 3D structures emitting light radiation having a second wavelength λ2 belonging to the spectrum of green light.

According to one example, the optoelectronic device comprises at least a third plurality of 3D structures having a third separation distance ds3 and a third diameter Φ3 of wires, said 3D structures emitting light radiation having a third wavelength λ3 belonging to the spectrum of blue light.

According to one example, ds1<ds2<ds3 and/or 1>Φ2>Φ3.

According to one example, the first wavelength λ1 is greater than 600 nm.

According to one example, the second wavelength λ2 is comprised between 500 nm and 600 nm.

According to one example, the third wavelength λ3 is less than 500 nm.

According to one example, the main wavelength λ of the light radiation is greater than or equal to 400 nm and/or is less than or equal to 700 nm.

According to one example, the main wavelength λ of light radiation is comprised between 500 nm and 650 nm.

The invention according to its third aspect comprises in particular the optional features below which can be used in combination or alternatively:

According to one example, the method comprises the following steps:
Providing a substrate comprising at least one surface layer allowing nucleation and growth of GaN, for example based on GaN, AlN, and/or other metal nitride,
Depositing a masking layer on the substrate, said masking layer comprising openings through which the surface layer is exposed,
Forming, by epitaxy from the exposed areas of the surface layer, GaN-based wires each extending from a base to a top in a longitudinal direction substantially perpendicular to the surface layer, said base being connected to the surface layer through the openings,
Forming, by epitaxy on the tops of GaN-based wires, InGaN-based pyramids.

According to one example, the surface layer has a thickness comprised between 1 nm and 200 nm, preferably between 10 nm and 200 nm.

According to one example, the formation of InGaN-based pyramids and/or the formation of GaN-based wires is carried out by metalorganic vapour phase epitaxy MOVPE.

According to one example, the openings of the masking layer are spaced by a pitch comprised between 50 nm and 700 nm.

According to one example, the openings of the masking layer are distributed so as to have a surface density greater than or equal to 4 μm⁻² and/or less than or equal to 400 μm⁻².

According to one example, the formation of InGaN-based pyramids is configured so that the InGaN-based pyramids have an indium level [In]≥10 at %.

According to one example, the formation of InGaN-based pyramids takes place at a temperature greater than or equal to 780° C.

According to one example, the masking layer comprises at least first, second and third pluralities of openings respectively having first, second and third pitches p1, p2, p3 and first, second and third opening diameters Φo1>Φo2>Φo3 such that p1<p2<p3 and Φo1>Φo2>Φo3, so as to simultaneously form first, second and third pluralities of 3D structures configured to emit light radiation having respectively first, second and third wavelengths λ1, λ2, λ3 different from each other and preferably such that λ1>λ2>λ3.

According to one example, the masking layer comprises first and second pluralities of openings having respectively first and second pitches p1, p2 and first and second opening diameters Φo1≤Φo2 such that p1<p2 and Φo1>Φo2, so as to simultaneously form first and second pluralities of 3D structures configured to emit light radiation respectively having first and second wavelengths λ1, λ2 different from each other and preferably such that λ1>λ2.

Unless incompatible, it is understood that the 3D structure, the manufacturing method, and the optoelectronic device may comprise, mutatis mutandis, any of the above optional features.

In the present invention, the 3D structure comprising an InGaN-based pyramid is in particular dedicated to the manufacture of 3D LEDs.

The invention can be implemented more broadly for various optoelectronic devices with a 3D structure, and in particular those comprising an active region.

Active region of an optoelectronic device means the region from which the majority of the light radiation supplied by this device is emitted, or the region from which the majority of the light radiation received by this device is captured.

The invention can therefore also be implemented in the context of laser or photovoltaic devices.

Unless explicitly mentioned, it is specified that, in the context of the present invention, the relative arrangement of a third layer interposed between a first layer and a second layer, does not necessarily mean that the layers are directly in contact with each other, but means that the third layer is either directly in contact with the first and second layers, or separated therefrom by at least one other layer or at least one other element.

The steps of forming the various elements are understood in a broad sense: they can be carried out in several sub-steps which are not necessarily strictly successive.

The diameter of a wire or the base of a pyramid means its largest transverse dimension. In the present invention, the wires do not necessarily have a circular cross section. In particular, in the case of GaN-based wires, this section can be hexagonal.

The diameter then corresponds to the distance separating two opposite tops of the hexagonal section. Alternatively, the diameter can correspond to an average diameter calculated from the diameter of a circle inscribed in the polygon of the cross section and the diameter of a circumscribed circle of this polygon. The diameter of a 3D structure is approximately equal to the diameter of the wire of this 3D structure.

Pencil shape means a shape comprising a cylindrical body, and a tapered tip at one end of this body. The barrel is preferably a straight cylinder. It may have a hexagonal or polygonal cross section. In the present patent application, its section is approximately constant along the height of the cylinder. It may nevertheless vary slightly, for example up to 5% or 10% of its surface, without this calling into question the definition of a cylindrical body stated above. The cylindrical body corresponds to the GaN-based wire in the present patent application. The tapered tip rests on one end of the cylindrical body. It preferably has the same base as the cylinder and extends, preferably continuously, converging towards a point or a top area. The tapered tip may optionally comprise one or more degrees. The tapered top corresponds to the top InGaN-based pyramid in the present patent application.

Wire means a 3D structure of elongated shape in the longitudinal direction. The longitudinal dimension of the wire, along z in the figures, is greater, and preferably much greater, than the transverse dimensions of the wire, in the plane xy in the figures. The longitudinal dimension is for example at least five times, and preferably at least ten times, greater than the transverse dimensions.

The surface density of 3D structures depends on the separation distance ds separating two adjacent 3D structures. It can in particular be inversely proportional to this distance ds according to k/ds² with k a factor of proportionality.

In the present patent application, the terms “concentration”, “level” and “content” are synonymous.

More particularly, a concentration can be expressed in relative units such as molar or atomic fractions (at %), or in absolute units such as the number of atoms per cubic centimetre (at·cm⁻³).

In the following, the concentrations are atomic fractions expressed in at %, unless otherwise indicated.

In the present patent application, the terms “light-emitting diode”, “LED” or simply “diode” are used synonymously. A “LED” can also be understood as a “micro-LED”.

In the following, the following abbreviations relating to a material M are optionally used:

M-i refers to the intrinsic or unintentionally doped material M, according to the terminology usually used in the field of microelectronics for the suffix -i.

M-n refers to the material M doped with N, N+ or N++, according to the terminology usually used in the field of microelectronics for the suffix -n.

M-p refers to the material M doped with P, P+ or P++, according to the terminology usually used in the field of microelectronics for the suffix -p.

A substrate, a layer, a device, “based” on a material M, means a substrate, a layer, a device comprising this material M only or this material M and possibly other materials, for example alloy elements, impurities or doping elements. Thus, a wire based on gallium nitride (GaN) can for example comprise gallium nitride (GaN or GaN-i) or doped gallium nitride (GaN-p, GaN-n). A pyramid based on gallium-indium nitride (InGaN) can for example comprise gallium-aluminium nitride (AlGaN) or gallium nitride with different contents of aluminium and indium (GaInAIN). In the context of the present invention, the material M is generally crystalline.

A reference mark, which is preferably orthonormal, comprising the axes x, y, z is shown in the appended figures.

In the present patent application, thickness for a layer and height for a device will preferably be considered. The thickness is taken in a direction normal to the main extension plane of the layer, and the height is taken perpendicular to the basal plane xy of the substrate. Thus, a buffer layer or a surface layer typically have a thickness along z, and a wire has a height along z.

The dimensional values agree to within the manufacturing and measuring tolerances. Thus, two identical separation distances ds or two diameters of wires which are identical in theory may have a slight dimensional variation in practice.

The terms “substantially”, “approximately”, “of the order of” mean, when they relate to a value, “within 10%” of this value or, when they relate to an angular orientation, “within 10°” of this orientation. Thus, a direction substantially normal to a plane means a direction having an angle of 90±100 relative to the plane.

To determine the geometry of the 3D structures, the crystallographic orientations and the compositions of the various elements (wire, pyramid, collar, active region in particular) of this 3D structure, it is possible to carry out Scanning Electron Microscopy (SEM) or Transmission Electron Microscopy (TEM) or else Scanning Transmission Electron Microscopy STEM analyses.

The crystallographic orientations of the various elements can be estimated directly from TEM or SEM images, or can be determined precisely by micro-diffraction within a TEM, for example.

TEM or STEM also lend themselves well to the observation and identification of structural defects, and in particular dislocations within the InGaN pyramids. Different techniques listed below in a non-exhaustive way can be implemented: dark field and bright field, weak beam, high angle diffraction HAADF (acronym for “High Angle Annular Dark Field”) imaging.

The chemical compositions of the various elements can be determined using the well-known EDX or X-EDS method, acronym for “energy dispersive x-ray spectroscopy”.

This method is well adapted for analysing the composition of small devices such as 3D LEDs. It can be implemented on metallurgical sections within a Scanning Electron Microscope (SEM) or on thin sections within a Transmission Electron Microscope (TEM). The optical properties of the various elements, and in particular the main emission wavelengths of InGaN-based pyramids and/or InGaN-based active regions, can be determined by spectroscopy.

Cathodoluminescence (CL) and photoluminescence (PL) spectroscopies are well adapted to optically characterise the 3D structures described in the present invention.

The techniques mentioned above allow in particular to determine whether an optoelectronic device with a 3D structure comprises an InGaN-based pyramid formed at the top of a GaN-based wire, as described in the present invention. The possible presence of a collar is also easily observed using these techniques.

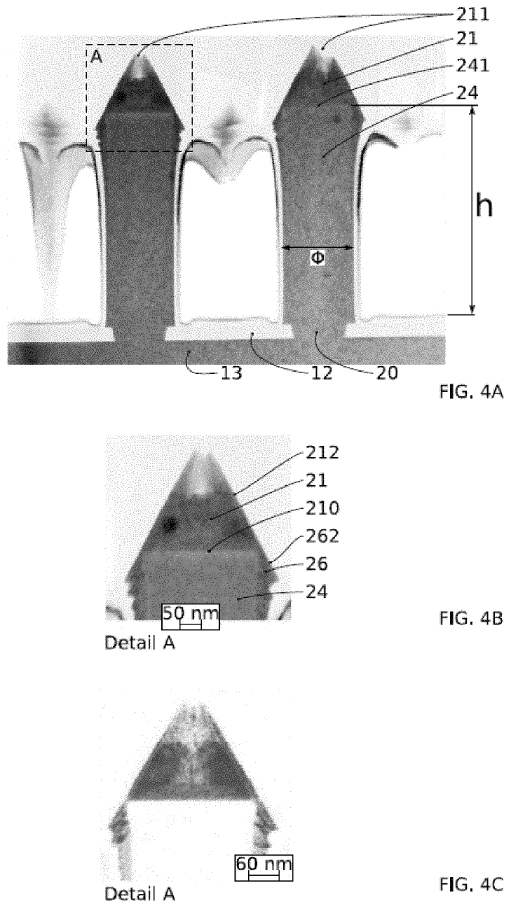

A first embodiment of a 3D structure according to the invention will now be described with reference to FIGS. 3 and 4A to 4C.

FIG. 3 illustrates a plurality of adjacent 3D structures 1 distributed on the same substrate 2a. The following description relating to one of these 3D structures naturally extends to the other 3D structures of this plurality, which are deemed to be substantially identical to each other.

The 3D structure 1 comprises at least one wire 24 and one pyramid 21 at the top of the wire 24. It is preferably formed directly from the substrate 2a. This substrate 2a may be in the shape of a stack comprising, in the direction z, a support 10, a surface layer 13 called the nucleation layer, and a masking layer 12. The substrate 2a is substantially plane and parallel to the plane xy.

The support 10 can in particular be made of sapphire to limit the lattice parameter mismatch with the GaN, or of silicon to reduce costs and for problems of technological compatibility. In the latter case, it can be in the shape of a 200 mm or 300 mm diameter wafer. It serves in particular as a support for 3D structures.

The nucleation layer 13 is preferably based on AlN. It may alternatively be based on other metal nitrides, for example GaN or AlGaN. This nucleation layer 13 can be any layer allowing the nucleation and growth of GaN known to the person skilled in the art. It can be formed on the silicon support 10 by epitaxy, preferably by metalorganic vapour phase epitaxy MOVPE. Advantageously it has a thickness less than or equal to 200 nm, preferably less than or equal to 100 nm, for example of the order of 50 nm. This allows to limit the mechanical stresses induced by this layer 13 on the support 10. This allows to avoid a detrimental curvature of the support 10. Such a thickness also allows to limit the appearance of structural defects in the nucleation layer 13. In particular, the growth of this nucleation layer 13 can be pseudomorphic, that is to say that the stresses of epitaxy (related in particular to the difference in lattice parameters between Si and AlN, GaN or AlGaN) can be elastically relaxed during growth. The crystalline quality of this nucleation layer 13 can thus be optimised.

The masking layer 12 is preferably made of a dielectric material, for example of silicon nitride Si₃N4. It can be deposited by chemical vapour deposition CVD on the nucleation layer 13. It partially masks the nucleation layer 13 and comprises preferably circular openings 120 exposing areas of the nucleation layer 13. These openings 120 typically have a dimension, for example a diameter Φo or an average diameter, comprised between 30 nm and 500 nm. The openings 120 can be distributed evenly within the masking layer 12, for example in the shape of an ordered array. The pitch, that is to say the distance separating the centres of two adjacent apertures 120, is preferably less than or equal to 700 nm. It can be comprised between 50 nm and 650 nm. The openings 120 advantageously have a surface density greater than 4 μm⁻². This ultimately allows to obtain 3D structures that are densely distributed on the substrate 2a. These openings 120 can be produced, for example, by UV or DUV (acronym for Deep UV) lithography, by electron beam lithography, or by NIL (acronym for Nanoimprint lithography). The formation of the masking layer 12 thus typically comprises a deposition of the dielectric material followed by the formation of the openings 120, typically by lithography. Such a masking layer 13 allows localised growth of a 3D structure at each opening 120. In particular, during a preliminary growth step called germination, a GaN-based seed 20 is formed at the opening 120 then fills said opening 120. The subsequent growth of the wire 24 then takes place from this seed 20, in a localised manner.

The wire 24 is based on GaN. It is preferably oriented parallel to z in a crystallographic direction [0001] corresponding to the axis c of a hexagonal crystallographic structure.

The GaN-based wire 24 can be formed by epitaxy, preferably by metalorganic vapour phase epitaxy MOVPE, in particular as defined in publication WO2012136665. The source of gallium in the form of organometallic precursor (precursor Ill) can typically be trimethyl gallium (TMGa) or triethyl gallium (TEGa). The nitrogen source can typically be ammonia (NH3) (precursor V). The growth temperature is preferably above 700° C., for example of the order of 1000° C. The gas pressure within the growth reactor is for example of the order of 425 Torr. The growth is preferably carried out under a neutral and/or reducing atmosphere, typically by adding nitrogen N2 and/or dihydrogen H2. The flows of the various gases can be adapted in a manner known to the person skilled in the art, in particular depending on the volume of the reactor.

The formation of the wire 24 can alternatively be carried out by molecular beam epitaxy MBE, by vapour phase epitaxy using chlorinated gaseous precursors HVPE (acronym for “Hydride Vapour Phase Epitaxy”), by chemical vapour deposition CVD and MOCVD (acronym for “MetalOrganic Chemical Vapour Deposition”).

Optionally, conventional steps of surface preparation of the seed 20 (chemical cleaning, heat treatment) can be carried out prior to the epitaxial growth of the wire 24.

The wire 24 can comprise an N-doped GaN-based region. In a known manner, this N-doped region can result from growth, implantation and/or activation annealing. The N doping can in particular be obtained directly during growth, from a source of silicon or germanium, for example by adding silane or disilane or germane vapour. The growth conditions required for the formation of such a wire 24 are widely known.

The wire 24 has a diameter 4) greater than or equal to 30 nm and/or less than or equal to 500 nm. This diameter 4) may be greater than the diameter of the opening 120 and of the seed 20 which gave rise to the wire 24. In this case, the base 240 of the wire 24 bears on the masking layer 12 of the substrate 2a. The cross section of the wire 24, in the plane xy, can typically have a more or less regular hexagonal shape. The wire 24 also has a height h greater than or equal to 150 nm. The top 241 of the wire 24 is preferably substantially flat and parallel to the plane xy, so as to accommodate the base 210 of the pyramid 21. The wire 24 preferably has an aspect ratio h/Φ greater than 1, and preferably greater than 5. This improves the crystalline quality of the wire 24 at the top 241 thereof. This also allows the top 241 to move away from the underlying planar substrate 2a. The local environment at the top 241 is thus not disturbed by the underlying planar substrate 2a. The formation of the InGaN pyramid 21 at the top 241 of the wire 24 is therefore not influenced by the planar substrate 2a.

The pyramid 21 is based on InGaN. It is preferably oriented in the same crystallographic direction as the wire 24. The formation of the InGaN-based pyramid 21 can be done by epitaxy, preferably by metalorganic vapour phase epitaxy MOVPE. The growth conditions required for the formation of the pyramid 21 differ from those required for the formation of the wire 24. A source of indium in the form of organometallic precursor, for example trimethyl-indium (TMIn) or triethyl-indium (TEIn), is in particular added to the sources of gallium (TEGa), trimethyl-gallium (TMGa) and nitrogen (NH3) to grow the InGaN-based material. The ratio of the precursor element of Indium (TMIn, TEIn) to all the precursors III (TEGa, TMGa and TMIn, TEIn . . . ) can be of the order of 0.3. The growth temperature can be around 800° C. The gas pressure within the growth reactor is for example of the order of 100 Torr. The V/III or In/III ratio, the pressure and the growth temperature can be adjusted according to the design of the epitaxy reactor and the target emission wavelength.

According to one possibility, the Ga/N element ratio may be greater than or equal to 100. This promotes growth of this InGaN-based material in the shape of a pyramid.

According to one possibility, the growth of the wire 24 is configured to obtain a Ga polarity at the top 241 of the wire 24. Such a polarity also promotes a pyramidal growth morphology.

The immediate environment at the top 241 of the wire 24 can also influence growth morphology. In particular, the proximity of other wires 24 and other adjacent tops 241 can locally modify the growth conditions of the InGaN-based material. In the context of the development of the present invention, it appeared that a high density of wires on the substrate 2a, in particular greater than 4 μm⁻², promotes pyramidal growth morphology. It also appeared that the more this surface density of wires 24 increases, the more the concentration of indium [In] incorporated in the pyramids 21 increases.

The growth temperature of the pyramid 21 is preferably greater than 700° C., preferably greater than 750° C. and advantageously of the order of 780° C. This allows to improve the crystalline quality of the pyramid 21. The formation of the InGaN-based pyramid 21 and the formation of the wire 24 can advantageously be done in one and the same growth frame.

FIGS. 4A and 4B are STEM-HAADF images of 3D structures obtained by MOVPE. These images show in particular that the wire 24 is practically free of structural defects, and that the pyramid 21 also has very good crystalline quality.

Structurally, the pyramid 21 comprises a base 210 resting on the top 241 of the wire 24, and a top 211 opposite the base 210 along z. The top 211 of the pyramid 21 can form a tip. It may possibly be more or less truncated or flattened (FIG. 4A). The base 210 of the pyramid 21 has a diameter Φp greater than or equal to the diameter 4) of the wire 24. This base 210 typically has the same more or less regular hexagonal shape as the section of the wire 24. The pyramid 21 extends from the base 210 to the top 211 while maintaining a transverse section, in the plane xy, of typically more or less regular hexagonal shape. The pyramid 21 thus comprises inclined sides or faces 212 extending from the base 210 to the top 211. In particular, these faces 212 may be six in number. The pyramid 21 has a height hp. This height hp may be of the order of the height h of the wire 24, preferably at least two times smaller, preferably at least 5 times smaller, for example about 10 times smaller than the height h of the wire 24. The pyramid 21 preferably has an aspect ratio hp/Φp of the order of 1. This corresponds to an inclination of the faces 212 of the order of 60° relative to the plane xy. Such faces 212 can advantageously correspond to {10-11} type planes. This allows to promote the incorporation of Indium in the pyramid 21, or in an active region 22 formed on these faces 212. According to another possibility, the faces 212 can be inclined at an angle of approximately 80° relative to the plane xy. Such an inclination of the faces 212 approximately coincides with semi-polar planes of the {20-21} type.

The pyramid 21 can extend under the base 210, around the top 241 of the wire 24, in the shape of a collar 26 for example (FIG. 4B). This collar 26 may comprise facets 262 as a continuation of the faces 212 of the pyramid 21. This collar 26 typically forms with the pyramid 21 a cap covering the top 241 of the wire 24. The collar 26 allows for example to improve the mechanical cohesion between the wire 24 and the pyramid 21. The collar 26 may have a significant height, of the order of a third or half the height of the pyramid, for example. It can also extend towards the base 240 of the wire 24, in the shape of a thin layer of a few nanometres, for example of the order of 1 to 5 nm, covering the vertical walls of the wire 24. The collar 26 may comprise a succession of irregular rings along z. This succession of irregular rings can thus have, in section along zx, a castellated section, forming steps or levels. The collar 26 is not necessarily in continuity with the pyramid 21. It can be independent thereof.

The InGaN-based pyramid 21 has an indium concentration preferably greater than or equal to 10 at %. Indium is distributed throughout the volume of the pyramid 21, as shown by the EDX mapping of the indium element shown in FIG. 4C. It is preferably distributed homogeneously within the pyramid 21, and in the collar 26 where appropriate.

To produce an optoelectronic device emitting or receiving light radiation, the 3D structure 1 can in particular comprise an active region 22 on the sides 212 of the pyramid 21, and a GaN-based region 23 on said active region 22, as illustrated in FIG. 3.

In the case of a LED, the active region 22 can typically comprise a plurality of quantum wells configured to emit light radiation at a main wavelength A. These quantum wells are for example based on InGaN. They can be conventionally separated from each other by barriers based on AlGaN.

The region 23 can be based on GaN, in particular based on P-doped GaN. It typically covers the active region 22 and allows to inject carriers into the active region 22. The growth of the region 23 over the active region 22 is preferably done so as to obtain a conformal layer. The thickness of this layer is preferably limited to a few tens of nanometres, for example less than 100 nm, or even less than 50 nm, so as to limit the reabsorption of the light radiation emitted by the active region 22. The edges of the layer forming the region 23 may have straight sides parallel to z, as illustrated in FIG. 3. Alternatively, these sides are inclined and extend on either side of the 3D structure. The sides of a region 23 of a given 3D structure can optionally join the sides of a region 23 of at least one adjacent 3D structure. In this case, a single region 23 in the shape of a substantially continuous layer can be formed on a plurality of 3D structures adjacent to each other.

The main wavelength of the light radiation emitted by the active region 22 depends in particular on the concentration of Indium in the quantum wells. The more the Indium content increases, the more the main wavelength increases towards the red light region of the visible spectrum. In particular, a concentration of Indium greater than 15 at % or 20 at % may result in emission of red light, having a main wavelength greater than or equal to 600 nm.

For this emission to be satisfactory in the context of a LED, the radiative efficiency must furthermore be high enough, for example of the order of 20%. To achieve such an efficiency, it is necessary for the active region 22 to have good crystalline quality.

The InGaN-based pyramid 21 of the 3D structure advantageously forms a transition region between the GaN-based wire 24 and the active InGaN-based region 22.

The concentration of indium incorporated can thus increase gradually, for example in stages, from the pyramid 21 to the active region 22. This allows to limit the appearance of structural defects in the active region 22. The concentrations of indium required in the active region 22 to emit light radiation in the red can thus be achieved without degrading the crystalline quality of the active region 22. Such a 3D structure comprising a GaN-n-based wire 24, an InGaN-based pyramid 21, an InGaN-based active region 22 and a GaN-p-based region 23 can therefore advantageously emit light radiation in the red with a high radiative efficiency.

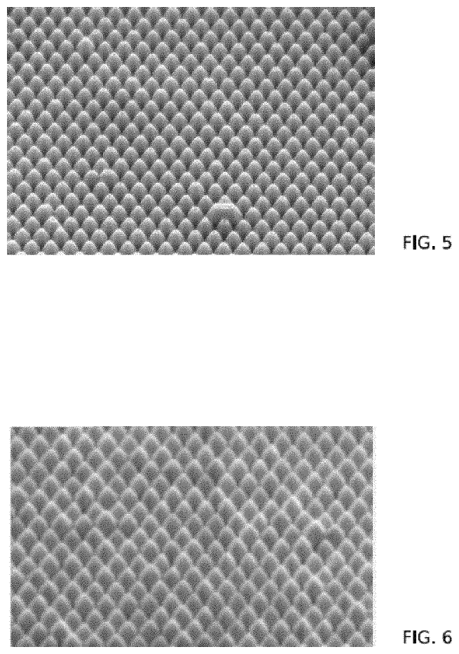

FIG. 5 shows a plurality of 3D structures as described previously, distributed over a dense array. In this example, the 3D structures have a diameter of approximately 200 nm and a surface density of the order of 20 μm⁻².

According to another exemplary embodiment, FIG. 6 shows a plurality of 3D structures having a diameter of approximately 100 nm and a surface density of the order of 25 μm⁻². The InGaN-based pyramids 21 are not covered in these examples.

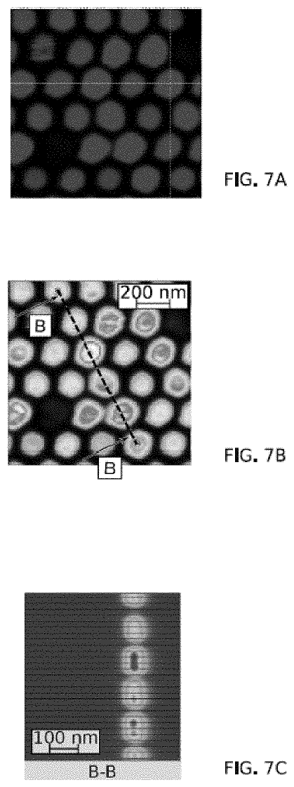

FIGS. 7A to 7C show some optical properties obtained by cathodoluminescence spectroscopy within a SEM on the 3D structures illustrated in FIG. 6. FIG. 7A shows in particular a mapping of cathodoluminescence intensity in top view of these 3D structures, at an acquisition wavelength of the order of 610 nm. It is clear that the vast majority of InGaN-based pyramids emit light at this wavelength when stimulated by the scanning of the electron beam of the SEM. FIG. 7B takes the data from FIG. 7A and presents them with increased contrast intensity dynamics. Different emission intensity thresholds of the pyramids at the wavelength λ≈620 nm are visible. A data profile indicated on the map of FIG. 7B is extracted and presented in FIG. 7C. Each point of the profile corresponds to a wavelength spectrum acquired over the range 250 nm-750 nm approximately. These spectra are gathered in FIG. 7C. It appears that the emission spectra of the pyramids are all centred on the wavelength λ≈620 nm. The width of the emission peaks is also quite small, of the order of a few tens of nanometres. Such spectral purity means in particular that the crystalline quality of the pyramids is good.

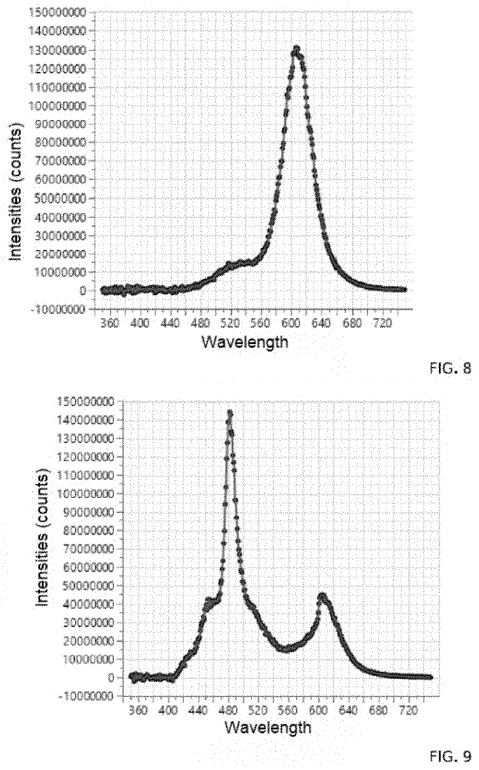

FIG. 8 shows a photoluminescence spectrum associated with this plurality of 3D structures. The most intense emission peak is centred around λ≈610 nm. The width at half the height of this peak is approximately 45 nm. This peak corresponds to the InGaN pyramids of 3D structures.

The radiative efficiency measured for these pyramids is of the order of 20%. This confirms that the pyramids of the 3D structures obtained according to the embodiments described above have a crystalline quality suitable for the production of red LEDs.

Such a plurality of 3D structures can therefore advantageously be implemented within a red 3D LED.

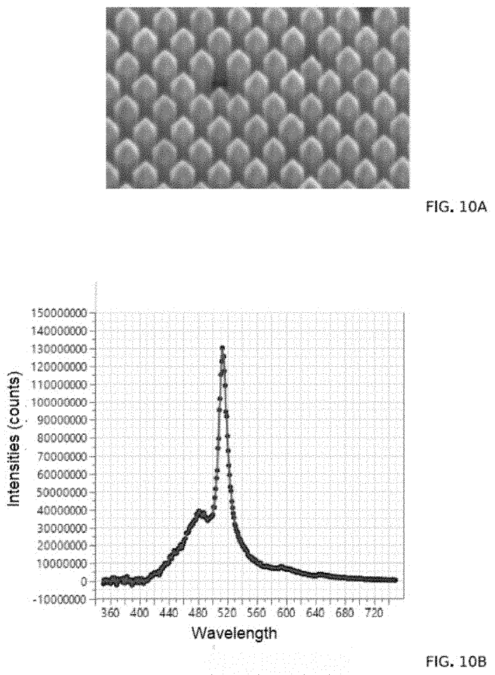

FIG. 9 shows another example of the photoluminescence spectrum obtained for 3D structures having a diameter of about 100 nm and a surface density of the order of 6 μm⁻² (not shown). The surface density of the 3D structures has here been divided by approximately 2 compared to the previous example. The most intense emission peak, corresponding to the InGaN pyramids of the 3D structures in this example, is centred around λ=480 nm (blue light domain). The width at half the height of this peak is approximately 20 nm. Such a plurality of 3D structures can therefore advantageously be implemented within a blue 3D LED. Another example of 3D structures is illustrated in FIG. 10A.

FIG. 10B shows a photoluminescence spectrum associated with the 3D structures of this example. The most intense emission peak is centred around λ=515 nm (green light range). The width at half the height of this peak is approximately 20 nm. This peak corresponds to the InGaN pyramids of the 3D structures shown in FIG. 10A. Such a plurality of 3D structures can therefore advantageously be implemented within a green 3D LED.

Thus, it appears through these various examples that by reducing the surface density of 3D structures for a given diameter, the main emission peak of 3D structures shifts towards small wavelengths. The width at mid-height of this peak also decreases.

Conversely, by increasing the diameter of 3D structures for a given surface density, the main emission peak of 3D structures shifts towards large wavelengths.

A wide range of wavelength settings can thus be obtained by varying the surface density and/or the diameter of 3D structures.

The 3D structures according to the invention can therefore be advantageously implemented in different types of optoelectronic devices, in particular in red 3D LEDs, green 3D LEDs, blue 3D LEDs, by adapting the surface density and the diameter of these 3D structures.

3D structures having different diameters 4) of wires 24 and different separation distances ds can be advantageously distributed on the same substrate 2a so as to form areas emitting light radiation at different main wavelengths. For example, the optoelectronic device can comprise:
a first area comprising 3D structures having a first diameter Φ1 and a first separation distance ds1, said 3D structures emitting light radiation at a first wavelength λ1 for example greater than 600 nm (red light range),
a second area comprising 3D structures having a second diameter Φ2 and a second separation distance ds2, said 3D structures emitting light radiation at a second wavelength λ2 for example comprised between 500 nm and 600 nm (green light range)
a third area comprising 3D structures having a third diameter Φ3 and a third separation distance ds3, said 3D structures emitting light radiation at a third wavelength λ3, for example less than 500 nm (blue light range).

These first, second, and third areas may be partially embedded within each other, such that there are first, second, and third pluralities of subsets respectively configured to emit in the red, green, and blue light domains.

The present invention also relates to a method for manufacturing a 3D LED as described through the preceding exemplary embodiments.

According to an advantageous embodiment, the method allows to simultaneously form the first, second and third areas of 3D structures configured to emit light radiation respectively having the first, second and third wavelengths λ1, λ2, λ3. In particular, such first, second and third 3D structure areas can be formed from a masking layer 12 deposited on the substrate 2b comprising first, second and third pluralities of openings 120 respectively having first, second and third pitch p1, p2, p3 and first, second and third opening diameters Φo1, Φo2, Φo3 such that p1<p2<p3 and/or Φo1>Φo2>Φo3.

The invention is not limited to the embodiments described above and extends to all the embodiments covered by the claims.

1. An optoelectronic device based on gallium nitride (GaN) comprising first and second pluralities of three-dimensional 3D structures, each 3D structure of the first and second pluralities of 3D structures comprising a pyramid made of a first InGaN-based material formed from a planar substrate, and a wire made of a second GaN-based material, different from the first material, said wire extending in a longitudinal direction perpendicular to the plane of the substrate between said substrate and a base of the InGaN-based pyramid, so that each 3D structure has the general shape of a pencil, wherein said first and second pluralities of 3D structures respectively having first and second separation distances ds1, ds2 between wires, and first and second diameters Φ1, Φ2 of wires, such that ds1<ds2 and Φ1>Φ2, said first and second pluralities of 3D structures emitting a light radiation having respectively first and second wavelengths λ1, λ2 such that λ1>λ2.

2. The optoelectronic device according to claim 1 wherein the GaN-based wire comprises a base resting on the planar substrate, and a top supporting the base (210) of the InGaN-based pyramid, said top being surrounded by an InGaN-based collar.

3. The optoelectronic device according to claim 1 wherein the base of the InGaN-based pyramid is substantially parallel to the plane of the substrate.

4. The optoelectronic device according to claim 1 wherein the InGaN-based pyramid has a base diameter Φp and the wire has a diameter Φ, the diameter Φ of the wire being less than or equal to the base diameter Φp.

5. The optoelectronic device according to claim 1 wherein each 3D structure further comprises an active InGaN-based region on at least one face of the InGaN-based pyramid, said active region being configured to emit or receive light radiation.

6. The optoelectronic device according to claim 1, wherein the 3D structures of the first plurality are spaced from each other by a separation distance ds1 less than or equal to 650 nm, and wherein the 3D structures of the second plurality are spaced from each other by a separation distance ds2 less than or equal to 650 nm.

7. The optoelectronic device according to claim 1 comprising at least first, second and third pluralities of 3D structures respectively having first, second and third separation distances ds1, ds2, ds3 and first, second and third diameters Φ1, Φ2 , Φ3 of wires such that ds1<ds2<ds3 and/or Φ1>Φ2>Φ3, said first, second and third pluralities of 3D structures emitting light radiation respectively having first, second and third wavelengths λ1, λ2, λ3 such that λ1>λ2>λ3.

8. A method for manufacturing an optoelectronic device based on gallium nitride (GaN) comprising a first and a second plurality of three-dimensional 3D structures for optoelectronics, each of the three-dimensional 3D structures comprising an InGaN-based pyramid and a GaN-based wire, the method comprising the following steps:
providing a substrate comprising at least one surface layer allowing nucleation and growth of GaN, for example based on GaN, AlN, and/or other metal nitride,
forming a masking layer on the substrate, said masking layer comprising openings through which the surface layer is exposed,
forming from the exposed areas of the surface layer the GaN-based wires each extending from a base to a top in a longitudinal direction substantially perpendicular to the surface layer, said base being connected to the surface layer through the openings,
forming on the tops of GaN-based wires InGaN-based pyramids
wherein the masking layer is formed with at least first and second pluralities of openings respectively having first and second pitches p1, p2 and first and second opening diameters Φo1, Φo2, such that p1<p2 and Φo1>Φo2, so as to simultaneously form the first and second pluralities of 3D structures respectively having first and second separation distances ds1, ds2 between wires, and first and second diameters Φ1, Φ2 of wires, such that ds1<ds2 and Φ1>Φ2, said first and second pluralities of 3D structures being configured to emit light radiation respectively having first and second wavelengths λ1, λ2 such that λ1>λ2.

9. The method according to claim 8 wherein the surface layer has a thickness comprised between 1 nm and 200 nm.

10. The method according to claim 8, wherein the formation of the InGaN-based pyramids and/or the formation of the GaN-based wires is carried out by metalorganic vapour phase epitaxy MOVPE.

11. The method according to claim 8 wherein the openings of the masking layer are spaced by a pitch comprised between 50 nm and 700 nm.

12. The method according to claim 8 wherein the openings of the masking layer are distributed so as to have a surface density greater than or equal to 4 μm⁻² and/or less or equal to 400 μm⁻².

13. The method according to claim 8 wherein the formation of the InGaN-based pyramids is configured so that the InGaN-based pyramids have an indium level [In]≥10 at %.

14. The method according to claim 8 wherein the formation of the InGaN-based pyramids is carried out at a temperature greater than or equal to 780° C.

15. The method according to claim 8 wherein the masking layer further comprises a third plurality of openings having a pitch p3 and a third opening diameter Φo3 such that p1<p2<p3 and Φo1>Φo2>Φo3, so as to simultaneously form first, second and third pluralities of 3D structures having respectively first, second and third separation distances ds1, ds2, ds3 between wires and first second and third diameters Φ1, Φ2 , Φ3 of wires such that ds1<ds2<ds3 and/or Φ1>Φ2>Φ3, said first, second and third pluralities of 3D structures being configured to emit light radiation having respectively first, second and third wavelengths λ1, λ2, λ3 such that λ1>λ2>λ3.

16. The optoelectronic device according to claim 1, wherein the 3D structures of the first plurality are spaced from each other by a separation distance ds1 less than or equal to 300 nm, and wherein the 3D structures of the second plurality are spaced from each other by a separation distance ds2 less than or equal to 300 nm.

17. The method according to claim 8, wherein the surface layer has a thickness comprised between 10 nm and 200 nm.
